(19) United States
(12) Patent Application Publication
(10) Pub. No.: US 2021/0335152 A1
(43) Pub. Date: Oct. 28, 2021

(54) FOLDABLE DISPLAY APPARATUS

(71) Applicant: WUHAN CHINA STAR OPTOELECTRONICS SEMICONDUCTOR DISPLAY TECHNOLOGY CO., LTD., Wuhan (CN)

(72) Inventor: Yongzhen JIA, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/326,928

(22) PCT Filed: Nov. 2, 2018
(86) PCT No.: PCT/CN2018/113752

§ 371 Date: Feb. 21, 2019

(30) Foreign Application Priority Data
Aug. 30, 2018 (CN) 201811002228.9

(51) Int. Cl. G09F 9/30; G06F 1/16; H01L 51/00; H01L 51/50

(52) U.S. Cl. CPC G09F 9/301; H01L 51/50; H01L 51/0097; G06F 1/1652

(57) ABSTRACT

A foldable display apparatus is provided. The foldable display apparatus comprises at least two film layers and a plurality of elastic devices, and a lubricating layer with higher optical transmittance is coated between adjacent two of the film layers.

### FIELD OF INVENTION

The present invention relates to a field of panel manufacturing, and more particularly, to a foldable display apparatus.

### BACKGROUND OF INVENTION

At present, due to excellent characteristics of organic light-emitting diodes (OLEDs), OLEDs are increasingly used on mobile phone screens. Among them, a foldable mobile phone is a research and development hotspot of the future electronic products, therefore, the research of a foldable OLED screen is indispensable.

In the existing technology, since deformation between the various film layers cannot be coordinated during a bending process of a flexible OLED screen, the interaction between the film layers greatly increases the stress level of the film material during the bending process. Moreover, the complex behavior combining with superelasticity, viscoelasticity, and plastic results in that the screen cannot be kept flat, when the screen is folded and then being unfolded. Irreparable wavy display strips resulting from the above are also a major problem that must be overcome during the flexible screen development.

### SUMMARY OF INVENTION

The present application provides a foldable display apparatus to solve the unrepairable display stripes, which are resulted from being bent, in the exist foldable display.

In order to solve the above-mentioned problems, the technical solutions provided by the present application are as follows:

The present application provides a foldable display apparatus, comprising an outer frame and a display panel disposed in the outer frame, wherein the display panel comprises:

at least two film layers;

a lubricating layer formed between adjacent two of the film layers; and

a plurality of elastic devices, one end of each one of the elastic devices connected with one of the film layers, the other end of each one of the elastic devices connected with the outer frame of the foldable display apparatus, and the elastic devices respectively corresponding to the film layers.

In the foldable display apparatus of the present application, the display panel comprises a support layer, a light emitting device layer, a polarizer layer, a touch layer, and a cover plate being sequentially disposed, wherein the at least two film layers are selected from at least two of the group consisting of the support layer, the light emitting device layer, the polarizer layer, the touch layer, and the cover plate;

wherein each one of the elastic devices is respectively connected with the support layer, the light emitting device layer, the polarizer layer, the touch layer, and the cover plate.

In the foldable display apparatus of the present application, each one of the elastic devices comprises a first fixing component, a second fixing component, and an elastic component, and the first fixing component and the second fixing component are connected by the elastic component.

In the foldable display apparatus of the present application, the first fixing component is fixed on the outer frame of the foldable display apparatus by welding or an adhesive, and the second fixing component is fixedly connected with the film layer by welding or an adhesive.

In the foldable display apparatus of the present application, the elastic component is a spring.

In the foldable display apparatus of the present application, an elastic coefficient of the elastic component fixedly connected to the film layer is gradually reduced in a direction from the support layer to the cover plate.

In the foldable display apparatus of the present application, the foldable display apparatus comprises two sets of the elastic devices, and the two sets of the elastic devices are respectively fixedly connected with two sides of the display panel.

In the foldable display apparatus of the present application, each set of the elastic devices comprises a plurality of the elastic devices, and a number of the elastic devices in each set of the elastic devices is the same as a number of the film layers.

In the foldable display apparatus of the present application, when the foldable display apparatus is in a bent state, a side of a bent region pulled by the elastic device is a non-light emitting area.

In the foldable display apparatus of the present application, the material of the lubricating layer is one of a polyalphaolefin synthetic oil, a polyether synthetic oil, and an alkyl benzene oil, or a combination of two or more thereof.

The application further provides a foldable display apparatus, comprising an outer frame and a display panel disposed in the outer frame, wherein the display panel comprises:

at least two film layers;

a lubricating layer formed between adjacent two of the film layers; and

at least one set of elastic devices, one end of each one of the elastic devices connected with one of the film layers, the other end of each one of the elastic devices connected with the outer frame of the foldable display apparatus, and the elastic devices respectively corresponding to the film layers;

wherein one set of the elastic devices comprises a plurality of the elastic devices, and a number of the elastic devices is the same as a number of the film layers.

In the foldable display apparatus of the present application, the display panel comprises a support layer, a light emitting device layer, a polarizer layer, a touch layer, and a cover plate being sequentially disposed, wherein the at least two film layers are selected from at least two of the group consisting of the support layer, the light emitting device layer, the polarizer layer, the touch layer, and the cover plate;

wherein each one of the elastic devices is respectively connected with the support layer, the light emitting device layer, the polarizer layer, the touch layer, and the cover plate.

In the foldable display apparatus of the present application, each one of the elastic devices comprises a first fixing component, a second fixing component, and an elastic component, and the first fixing component and the second fixing component are connected by the elastic component.

In the foldable display apparatus of the present application, the first fixing component is fixed on the outer frame of the foldable display apparatus by welding or an adhesive, and the second fixing component is fixedly connected with the film layer by welding or an adhesive.

In the foldable display apparatus of the present application, the elastic component is a spring.

In the foldable display apparatus of the present application, an elastic coefficient of the elastic component fixedly connected to the film layer is gradually reduced in a direction from the support layer to the cover plate.

In the foldable display apparatus of the present application, the foldable display apparatus comprises two sets of the elastic devices, and the two sets of the elastic devices are respectively fixedly connected with two sides of the display panel.

In the foldable display apparatus of the present application, each set of the elastic devices comprises a plurality of the elastic devices, and a number of the elastic devices in each set of the elastic devices is the same as a number of the film layers.

In the foldable display apparatus of the present application, when the foldable display apparatus is in a bent state, a side of a bent region pulled by the elastic device is a non-light emitting area.

In the foldable display apparatus of the present application, the material of the lubricating layer is one of a polyalphaolefin synthetic oil, a polyether synthetic oil, and an alkyl benzene oil, or a combination of two or more thereof.

The beneficial effect: the present application reduces the friction between the film layers by providing a lubricating layer between the film layers, and applies the traction force to each of the film layers and coordinates deformation between the film layers by using the elastic devices, so that the film layers can sufficiently slip relative to each other during the bending process, which ensures the flatness of the film layers.

### DESCRIPTION OF DRAWINGS

In order to more clearly illustrate the technical solutions in the embodiments or the prior art, the following drawings, which are intended to be used in the description of the embodiments or the prior art, will be briefly described. It will be apparent that the drawings and the following description are only some embodiments of the present invention. Those of ordinary skill in the art may, without creative efforts, derive other drawings from these drawings.

FIG. 1 is a film layers structural diagram of a display apparatus according to embodiment 1 of the present application.

FIG. 2 is the film layers structural diagram of the display panel in an unfolded state according to embodiment 1 of the present application.

FIG. 3 is the film layers structural diagram of the display panel in an outwardly bent state according to embodiment 1 of the present application.

FIG. 4 is the film layers structural diagram of the display panel in an inwardly bent state according to embodiment 1 of the present application.

FIG. 5 is a film layers structural diagram of a display panel according to embodiment 2 of the present application.

FIG. 6 is a first film layers structural diagram of the display panel in an outwardly bent state according to embodiment 2 of the present application.

FIG. 7 is a second film layers structural diagram of the display panel in an inwardly bent state according to embodiment 2 of the present application.

### DETAILED DESCRIPTION OF PREFERRED EMBODIMENTS

In the following detailed description of the preferred embodiments, reference is made to the accompanying drawings which form a part hereof, and in which is shown by way of illustration specific embodiments in which the invention may be practiced. In this regard, directional terminology, such as “top”, “bottom”, “front”, “back”, “left”, “right”, “inside”, “outside”, “side”, etc., is used with reference to the orientation of the figure(s) being described. As such, the directional terminology is used for purposes of illustration and is in no way limiting. Throughout this specification and in the drawings like parts will be referred to by the same reference numerals.

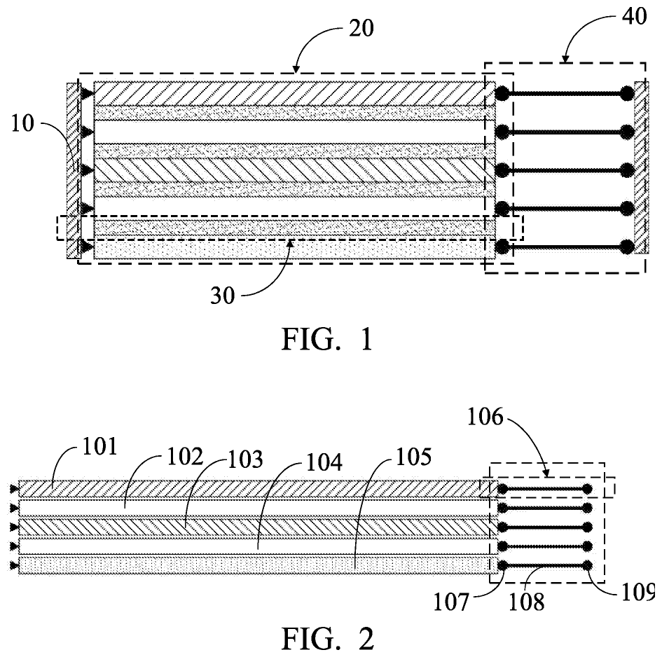

Please refer to FIG. 1, FIG. 1 is a film layers structural diagram of a display apparatus according to embodiment 1 of the present application.

A foldable display apparatus includes an outer frame 10 and a display panel disposed in the outer frame 10. The foldable display apparatus includes a plurality of film layers 20, a lubricating layer 30, and at least one set of elastic devices 40.

Please refer to FIG. 2, FIG. 2 is a film layers structural diagram of a display panel in an unfolded state according to embodiment 1 of the present application.

The display panel includes a support layer 105, a light emitting device layer 104, a polarizer layer 103, a touch layer 102, a cover plate 101, and other film layers (not shown) which are sequentially stacked and disposed. The film layers are selected from at least two of the group consisting of the support layer 105, the light emitting device layer 104, the polarizer layer 103, the touch layer 102, and the cover plate 101.

In one embodiment, the structure of the display panel in this embodiment is not limited to the above-mentioned film layers structure, and a position between the film layers can also be changed. For example, the touch layer 102 may be located on an upper surface or a lower surface of the cover plate 101, or on an upper surface or a lower surface of an encapsulation film layer (not shown) or the like.

In one embodiment, the lubricating layer 30 is disposed between any adjacent two film layers or any partially adjacent two film layers, the lubricating layer 30 being used to reduce the friction between the film layers. In the present application, the lubricating layer 30 has higher optical transmittance, and the thickness of the lubricating layer 30 is much smaller than the thickness of each of the film layers. Therefore, the thickness of the lubricating layer 30 can be negligible.

The use of the lubricating layer 30 replaces traditional optical adhesive and reduces the friction between the film layers. Therefore, the film layers can sufficiently slip relative to each other during the bending process, and the hardness and the compressive capacity of the whole flexible module can be improved.

In one embodiment, main material of the lubricating layer 30 includes one of a polythene synthetic oil, a polyether synthetic oil, an alkyl benzene oil, other mineral oil, or a combination of two or more thereof. The material of the lubricating layer 30 is not limited to the above several compositions.

In one embodiment, optical clear adhesive (OCA) can be selected for adhering partial film layers in order to reduce the tensile stress on a bending surface of the film layer and prevent the damage of the optical device.

The foldable display apparatus includes at least one set of the elastic devices 40. A set of the elastic devices 40 includes a plurality of elastic devices 106, and a number of the elastic devices 106 is the same as a number of the film layers.

Each one of the elastic devices 106 is respectively connected with the support layer 105, the light emitting device layer 104, the polarizer layer 103, the touch layer 102, and the cover plate 101.

Please refer to FIG. 2, the elastic device 106 includes a first fixing component 107, a second fixing component 109, and an elastic component 108. The first fixing component 107 and the second fixing component 109 are connected by the elastic component 108.

In one embodiment, the elastic component 108 can be a spring.

Please refer to FIG. 1 and FIG. 2, the foldable display apparatus includes a set of elastic devices 40, and the set of the elastic devices 40 includes a plurality of elastic devices 106.

The first fixing component 107 of the elastic device 106 is connected with each of the film layers of the display panel, and the second fixing component 109 of the elastic device 106 is connected with the outer frame 10 of the foldable display apparatus.

The second fixing component 109 is fixed on the outer frame 10 of the foldable display apparatus by welding or an adhesive, the first fixing component 107 is fixedly connected with the film layer by welding or an adhesive. The other side of each of the film layers of the display panel that is not connected with the elastic device 106 is fixed to the outer frame 10 of the foldable display apparatus or other structure by an adhesive.

FIG. 2 is a schematic view showing the display panel of the present application in a stretched state or in a freely stretched state. The specific initial state of the elastic device 106 can be set according to actual conditions.

In one embodiment, the elastic component 108 is in a stretched state. The elastic devices 106 respectively correspond to the film layers in the display panel, and the elastic devices 106 apply a slight tensile stress on each of the film layers.

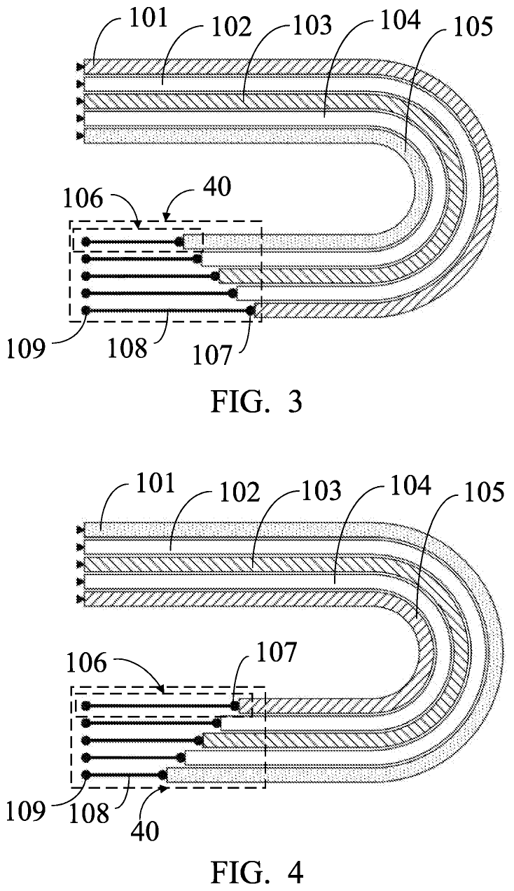

Please refer to FIG. 3, FIG. 3 is a film layers structural diagram of the display panel in an outwardly bent state according to embodiment 1 of the present application.

When the display panel is in an outwardly bent state, the cover plate 101 is furthest from the first fixing component 107 of the elastic device 106, and the support layer 105 is closest to the first fixing component 107. Therefore, the elastic component 108 corresponding to different film layers has different stretching lengths, that is, the tensile stress of the elastic device 106 corresponding to each of the film layers is different.

In this application, the elastic devices 106 with different elastic coefficients are selected, that is, the tensile stress of each of the film layers is the same (assumed that each of the film layers can withstand the same maximum tensile stress).

In one embodiment, the elastic coefficient of the elastic device 106 corresponding to the cover plate 101 is the smallest, and the elastic coefficient of the elastic device 106 corresponding to the support layer 105 is the largest. The elastic coefficient of the elastic component 108 fixedly connected to the film layer is gradually reduced in a direction from the support layer 105 to the cover plate 101. The elastic component 108 connected to the support layer has the greatest elastic coefficient, and the elastic component 108 connected to the protection cover plate has the smallest elastic coefficient.

Each of the film layers is made of different material and has different thickness, that results in the max tensile stress, which each of the film layers can withstand, is different. Therefore, the selection of the elastic coefficient of the elastic component 108 in each elastic device 106 requires a stress test and a reasonable setting for each of the film layers.

Please refer to FIG. 4, FIG. 4 is a film layers structural diagram of the display panel in an inwardly bent state according to embodiment 1 of the present application.

The cover plate 101 located at the outermost layer of the display panel is closest to the first fixing component 107 of the elastic device 106, and the support layer 105 located at the innermost layer of the display panel is farthest from the first fixing component 107 of the elastic device 106. Therefore, the elastic device 106 corresponding to different film layers needs different stretching lengths, and the tensile stress of the elastic device 106 corresponding to each of the film layers is different.

In the display panel of the present application, if the stress applied to each of the film layers is the same (assuming that each of the film layers can withstand the same maximum tensile stress), the elastic component 108 corresponding to the cover plate 101 has a smallest stretching length, so the elastic component 108 connected to the cover plate 101 has the largest elastic coefficient.

In one embodiment, the elastic component 108 corresponding to the support layer 105 has the largest stretching length, and the elastic component 108 corresponding to the support layer 105 has the smallest elastic coefficient.

In one embodiment, the present application may adjust the material or thickness of each of the film layers such that the elastic coefficient of the elastic component 108 in an inwardly bent state is the same as that in an outwardly bent state.

Please refer to FIG. 3, when the display panel is in the outwardly bent state, a side of a bent region pulled by the elastic device 106 can be controlled to be in a black screen state, that is, a non-light emitting area.

The foldable display apparatus is further provided with a middle frame or a mechanism outer frame (not shown). During an outwardly bending process, an innermost film layer is blocked and restricted by the middle frame or the mechanism outer frame. The pulling force of the elastic device 106 connected with the film layer is opposite to a pressure direction of the middle frame, which ensures that the respective film layers do not separate from each other during the outwardly bending process.

In one embodiment, the protective support layer 105 in the display panel of the present application may be selected from a polymer material, such as polyethylene terephthalate (PET), polyethylene naphthalate (PEN), or an ultra-thin metal or a glass material.

In this embodiment, the set of elastic devices are disposed on a side of the display panel, and applies the traction force to each of the film layers and coordinates deformation between the film layers by using the elastic devices, so that each of the film layers can sufficiently slip relative to each other during the bending process, which ensures the flatness of the film layers. Moreover, the stress tests are performed separately on each of the film layers, if the film material passes the bending test, it can be applied in the module structure, effectively reducing the development cycle of the flexible OLED module.

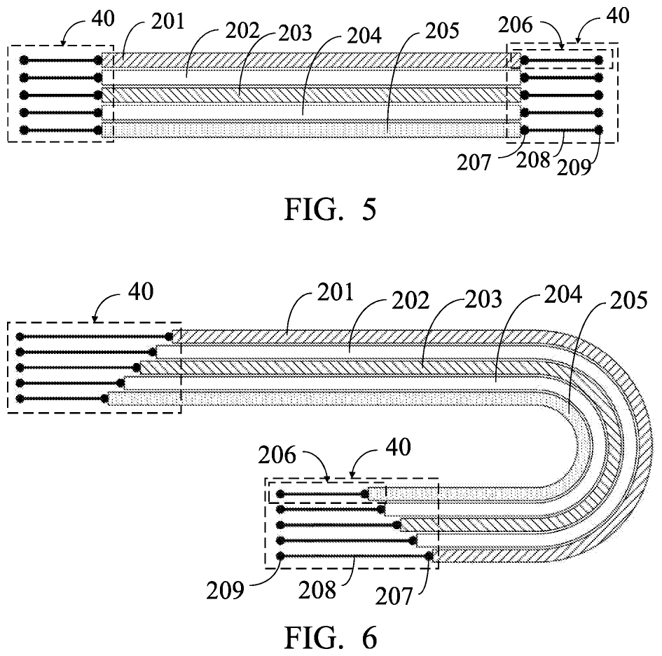

Please refer to FIG. 5, FIG. 5 is a film layers structural diagram of a display panel according to embodiment 2 of the present application.

The foldable display apparatus includes two sets of the elastic devices 40, and each set of the elastic device 40 is connected with a side of the display panel. Each set of the elastic devices 40 includes a plurality of the elastic devices 206, and a number of the elastic devices 206 in each set of the elastic devices 40 is the same as a number of the film layers. The other structures in this embodiment are the same as those in embodiment 1, no further description is made herein.

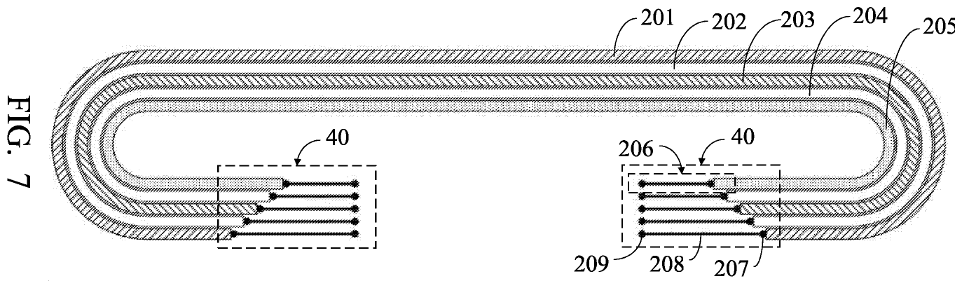

Please refer to FIG. 6, FIG. 6 is a first film layers structural diagram of the display panel in an outwardly bent state according to embodiment 2 of the present application.

The display panel is in an outwardly bent state, the display is bent in the middle or at a position on the display.

Please refer to FIG. 7, FIG. 7 is a second film layers structural diagram of the display panel in an inwardly bent state according to embodiment 2 of the present application.

Both ends of the display are bent at the same time.

Under the premise that the elastic coefficient of each elastic component 208 connected to the both ends of each film structure are the same, the stretched state of the two sets of the elastic components 208 is the same as that of embodiment 1.

In one embodiment, a bent region near a side of the elastic device 206 is a non-light emitting area when the foldable display apparatus is bent.

The present application provides a foldable display apparatus, the foldable display apparatus includes a plurality of film layers and a plurality of elastic devices, and a lubricating layer with a higher optical transmittance is coated between adjacent two of the film layers. The present application reduces the friction between the layers by coating the lubricating layer between the film layers, and applies the traction force to each of the film layers and coordinates deformation between the film layers by using the elastic devices, so that the film layers can sufficiently slip relative to each other during the bending process, which ensures the flatness of the film layers. In addition, the stress tests can be performed separately on each of the film layers, and which effectively reduces the development cycle of the flexible OLED module.

In view of the above, although the present invention has been disclosed by way of preferred embodiments, the above preferred embodiments are not intended to limit the present invention, and one of ordinary skill in the art, without departing from the spirit and scope of the invention, the scope of protection of the present invention is defined by the scope of the claims.

What is claimed is:

1. A foldable display apparatus, comprising an outer frame and a display panel disposed in the outer frame, wherein the display panel comprises:
at least two film layers;
a lubricating layer formed between adjacent two of the film layers; and
a plurality of elastic devices, one end of each one of the elastic devices connected with one of the film layers, the other end of each one of the elastic devices connected with the outer frame of the foldable display apparatus, and the elastic devices respectively corresponding to the film layers.

2. The foldable display apparatus according to claim 1, wherein the display panel comprises a support layer, a light emitting device layer, a polarizer layer, a touch layer, and a cover plate being sequentially disposed, wherein the at least two film layers are selected from at least two of the group consisting of the support layer, the light emitting device layer, the polarizer layer, the touch layer, and the cover plate;
wherein each one of the elastic devices is respectively connected with the support layer, the light emitting device layer, the polarizer layer, the touch layer, and the cover plate.

3. The foldable display apparatus according to claim 2, wherein each one of the elastic devices comprises a first fixing component, a second fixing component, and an elastic component, and the first fixing component and the second fixing component are connected by the elastic component.

4. The foldable display apparatus according to claim 3, wherein the first fixing component is fixed on the outer frame of the foldable display apparatus by welding or an adhesive, and the second fixing component is fixedly connected with the film layer by welding or an adhesive.

5. The foldable display apparatus according to claim 3, wherein the elastic component is a spring.

6. The foldable display apparatus according to claim 3, wherein an elastic coefficient of the elastic component fixedly connected to the film layer is gradually reduced in a direction from the support layer to the cover plate.

7. The foldable display apparatus according to claim 1, wherein the foldable display apparatus comprises two sets of the elastic devices, and the two sets of the elastic devices are respectively fixedly connected with two sides of the display panel.

8. The foldable display apparatus according to claim 7, wherein each set of the elastic devices comprises a plurality of the elastic devices, and a number of the elastic devices in each set of the elastic devices is the same as a number of the film layers.

9. The foldable display apparatus according to claim 1, wherein when the foldable display apparatus is in a bent state, a side of a bent region pulled by the elastic device is a non-light emitting area.

10. The foldable display apparatus according to claim 1, wherein the material of the lubricating layer is one of a polyalphaolefin synthetic oil, a polyether synthetic oil, and an alkyl benzene oil, or a combination of two or more thereof.

11. A foldable display apparatus, comprising an outer frame and a display panel disposed in the outer frame, wherein the display panel comprises:
at least two film layers;
a lubricating layer formed between adjacent two of the film layers; and
at least one set of elastic devices, one end of each one of the elastic devices connected with one of the film layers, the other end of each one of the elastic devices connected with the outer frame of the foldable display apparatus, and the elastic devices respectively corresponding to the film layers;
wherein one set of the elastic devices comprises a plurality of the elastic devices, and a number of the elastic devices is the same as a number of the film layers.

12. The foldable display apparatus according to claim 11, wherein the display panel comprises a support layer, a light emitting device layer, a polarizer layer, a touch layer, and a cover plate being sequentially disposed, wherein the at least two film layers are selected from at least two of the group consisting of the support layer, the light emitting device layer, the polarizer layer, the touch layer, and the cover plate;
wherein each one of the elastic devices is respectively connected with the support layer, the light emitting device layer, the polarizer layer, the touch layer, and the cover plate.

13. The foldable display apparatus according to claim 12, wherein each one of the elastic devices comprises a first fixing component, a second fixing component, and an elastic component, and the first fixing component and the second fixing component are connected by the elastic component.

14. The foldable display apparatus according to claim 13, wherein the first fixing component is fixed on the outer frame of the foldable display apparatus by welding or an adhesive, and the second fixing component is fixedly connected with the film layer by welding or an adhesive.

15. The foldable display apparatus according to claim 13, wherein the elastic component is a spring.

16. The foldable display apparatus according to claim 13, wherein an elastic coefficient of the elastic component fixedly connected to the film layer is gradually reduced in a direction from the support layer to the cover plate.

17. The foldable display apparatus according to claim 11, wherein the foldable display apparatus comprises two sets of the elastic devices, and the two sets of the elastic devices are respectively fixedly connected with two sides of the display panel.

18. The foldable display apparatus according to claim 17, wherein each set of the elastic devices comprises a plurality of the elastic devices, and a number of the elastic devices in each set of the elastic devices is the same as a number of the film layers.

19. The foldable display apparatus according to claim 11, wherein when the foldable display apparatus is in a bent state, a side of a bent region pulled by the elastic device is a non-light emitting area.

20. The foldable display apparatus according to claim 11, wherein the material of the lubricating layer is one of a polyalphaolefin synthetic oil, a polyether synthetic oil, and an alkyl benzene oil, or a combination of two or more thereof.
